(19) United States
(12) Patent Application Publication
(10) Pub. No.: US 2003/0197176 A1
(43) Pub. Date: Oct. 23, 2003

(54) Silicon on insulator standoff and method for manufacture thereof

(75) Inventors: James P. Spallas, Dublin, CA (US); Andres Fernandez, Dublin, CA (US); Thomas DeBey, SanJose, CA (US); Lawrence P. Muray, Moraga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Glimmerglass Networks, Inc., Hayward, CA

(21) Appl. No.: 10/128,368

(22) Filed: Apr. 22, 2002

(51) Int. Cl. H01L 29/04

(52) U.S. Cl. 257/58

(57) ABSTRACT

Method for fabricating ultrathin gaps producing ultrashort standoffs in array structures includes sandwiching a patterned device layer between a silicon standoff layer and a silicon support layer, providing that the back surfaces of the respective silicon support layer and the standoff layer are polished to a desired thickness corresponding to the desired standoff height on one side and to at least a minimum height for mechanical strength on the opposing side, as well as to a desired smoothness. Standoffs and mechanical supports are then fabricated by etching to produce voids with the dielectric oxides on both sides of the device layer serving as suitable etch stops. Thereafter, the exposed portions of the oxide layers are removed to release the pattern, and a package layer is mated with the standoff voids to produce a finished device. The standoff layer can be fabricated to counteract curvature.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

This invention is related to the fabrication of three-dimensional array structures, and particularly to structures requiring separations or standoffs of about 2 μm to about 300 μm. A standoff or gap spacing in this range is referred to as an ultrathin gap.

It is desirable that MEMS devices be mass manufactured from silicon based wafers. Large wafer diameters are desired to minimize the cost of the MEMS devices. Silicon wafers with diameters less than 75mm are not commonly used for mass manufacturing devices.

One embodiment of MEMS devices requires ultrathin gaps to optimize performance. The spacing is set by a silicon standoff, i.e., the spacing between an electrode and a mirror. The thickness and accuracy in surface polishing generally defines the ultrathin gap tolerances and sets the lower limit of the ultrathin spacing.

One problem in manufacturing MEMS devices that require ultrathin gaps is handling wafers that are thinned to the desired ultrathin gap spacing. These wafers are fragile in general, and extremely fragile for wafers with diameters greater than 100 mm. Larger wafers less than 250 μm thick are uncommon, which necessitates the search for a more robust and yet accurate manufacturing technique.

### SUMMARY OF THE INVENTION

According to the invention, a method is provided for fabricating ultrathin gaps producing ultrathin standoffs in array structures manufactured in silicon or silicon on insulator (SOI) wafers. The method includes preparing a pattern in an exposed device layer (for example, a mirror) on a buried dielectric layer (typically silicon dioxide commonly referred to as the buried oxide or BOX in a silicon support layer, commonly referred to as the handle of a SOI wafer, then sandwiching the patterned device layer between silicon substrate wafers, then having the back surfaces of the respective wafers (namely, the silicon substrate and the SOI substrate) polished to a desired ultrathin gap on the standoff wafer side and to at least a minimum height for the mechanical strength on the opposing or mechanical support wafer side, as well as to a desired smoothness. Etching of voids in the standoff layer and the mechanical support layer then exposes the device layer. Dielectrics on one or both sides of the patterned device layer serve as suitable etch stops and protection for the surfaces of the patterned device layer. Thereafter, the exposed portions of the dielectric layers are removed and the pattern is released, and then an array package, such as an array of electrodes on an insulative substrate, herein a ‘package,’ is mated with the standoff voids in proper registration to the polished standoff layer to produce a finished device.

If the stress of the SOI wafer is matched by the stress of the silicon substrate, then the inherent radius of curvature of the composite wafer caused by the stress at the BOX/silicon standoff interface is reduced. In particular, if there is a prestressed warp caused by the dielectric in the silicon structure of the SOI wafer, then the prestressed warp in the silicon substrate caused by a dielectric on that substrate, when bonded to the SOI wafer, tends to counteract the stress of the SOI wafer resulting in a composite wafer with a reduced warp.

In some embodiments, the standoff is part of the substrate wafer. In other cases, for example, where the silicon substrate is patterned and used for example for tilt limiting or the like, the standoff is part of the SOI wafer. Similarly, dielectric layers formed as coatings over the pattern are optionally used to insulate the silicon substrate from the SOI structure, in which case the dielectric also serves as an etch stop. In cases where it is desirable to have an electrical connection between the patterned device layer and the substrate or the SOI structure, all or part of the dielectric layers may be omitted and other means may be provided for an etch stop.

Structures manufactured as herein disclosed are intended to minimize the risk of failure during processing, postprocessing and packaging and thereby maximizing manufacturing yield, since the standoff can be reduced while maintaining the strength in the composite wafer which contains the pattern defining the MEMS device. In particular, this is a manufacturing-enabling technique for larger wafer-size-based processing, particularly as it relates to MEMS devices. This technique is attractive in the manufacture of MEMS devices from wafers greater than or equal to 100 mm in diameter. This invention has particular application to the fabrication of MEMS structures on bulk substrates, which are typically SOI. The particular use of the technology is in mirror-to-electrode spacing. For spacing greater than about 250 μm, other technologies are more practical for wafers of less than 100 mm in diameter.

The invention will be better understood by reference to the following detailed description in conjunction with the accompanying drawings.

### BRIEF DESCRIPTION OF THE DRAWINGS

FIG. 1 is a side cross-sectional view of a known MEMS mirror module of an array.

FIGS. 2A-2F is a side cross-sectional view illustrating a first process according to the invention.

FIGS. 3A-3F is a side cross-sectional view illustrating a second process according to the invention.

FIGS. 4A-4F is a side cross-sectional view illustrating a third process according to the invention.

FIGS. 5A-5F is a side cross-sectional view illustrating a second process according to the invention.

### DETAILED DESCRIPTION OF THE INVENTION

Referring to FIG. 1, there is shown a cross-section of a known MEMS mirror module 100. This structure is not necessarily prior art. It is however illustrative of the elements of structures of the type of interest. Layer 12 has a metallized surface 14. It is formed with a gimbal ring 16 and a support periphery 18 on an insulator layer or BOX 20. The layer 12 is spaced by a predefined gap 21 from the mounting surface on which is a set of electrodes 22, 24 by a standoff 26 encircling the mirror portion 14 of the metallized layer 12. The standoff 26 and the electrodes are mounted on the surface of a package layer 28. There are vias 30, 32 through the package layer 28 to provide electrical conduits to the electrodes 22, 24.

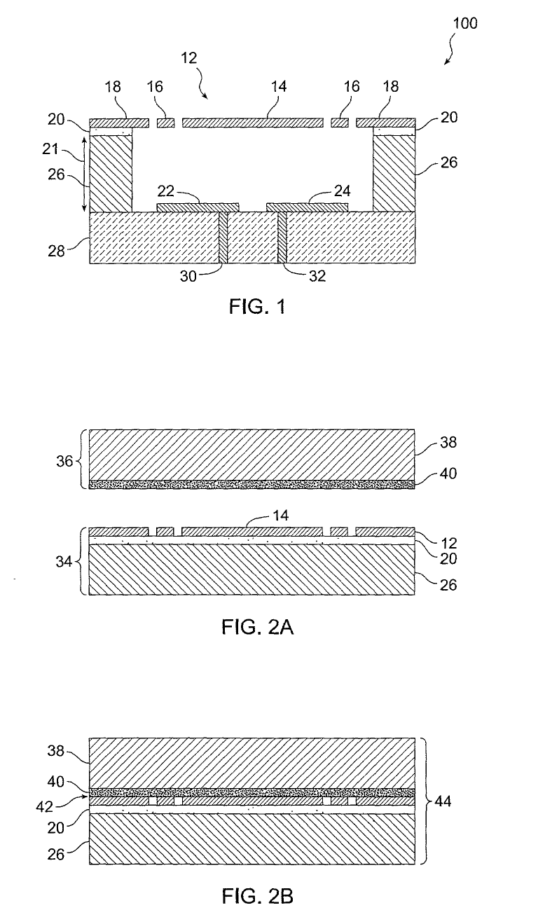

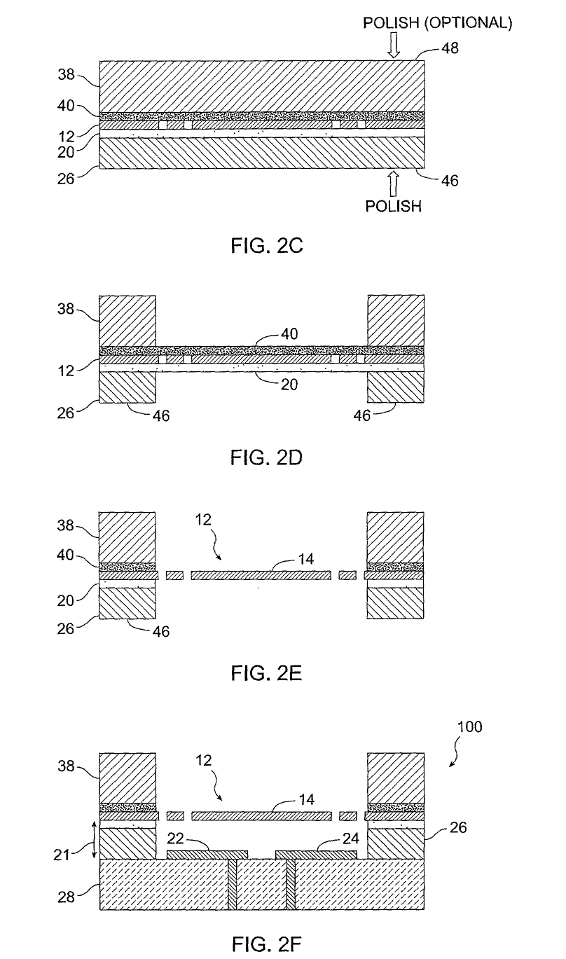

Beginning with FIG. 2A, a manufacturing process according to the invention is illustrated. Referring to FIG. 2A, there is shown a side cross-sectional view of two wafers, one that includes the standoff and the other to provide support, as shown prior to bonding according to the invention. Initially an SOI wafer 34 provides inherent support. It comprises a handle layer 26, a BOX 20, which is a dielectric that is resistant to etchant as hereinafter explained, and a device layer 12. The device layer 12 is first patterned by etching to define the mirror and gimbal pattern for all devices in an array, of which this is one example device.

Referring to FIG. 2A and FIG. 2B, thereafter a silicon wafer 36 comprising a silicon substrate 38 with an insulator layer 40, which is a dielectric that is resistant to etchant as hereinafter explained, is bonded to the SOI wafer 34 with the device layer 12 juxtaposed to the insulator layer 40 at a bonding interface 42 to form a composite wafer 44. The silicon substrate 38 thereupon becomes the mechanical support for the device layer 12, and the SOI handle can become a standoff layer without having to compromise standoff height for strength. The bonding of the insulator layer 40 to the silicon substrate 38 creates a stress which gives the wafer a nonzero radius of curvature. (This prestressed warp, when the wafer 36 is bonded to the SOI wafer 34, tends to counteract the stress of the SOI wafer 34 resulting in a composite wafer with a reduced warp.)

thereafter the manufacturing process proceeds to a polishing step wherein the back side 46 of the SOI handle 26 is polished to a desired standoff height and ultrafine smoothness. Optionally, the back side 48 of the silicon substrate 38 may also be polished as required by device design (FIG. 2C).

With the standoff height having been established, then by a process of etching, voids are formed in the standoff layer and the mechanical support layer to expose the device layer (FIG. 2D). The etchant-resistant dielectric insulator layers 20, 40 on one or both sides of the patterned device layer serve as etch stops to protect the surfaces of the patterned device layer.

Referring to FIG. 2E, the dielectric insulator layers 20, 40 within the cavities so formed are removed to release the device layer 12 and in particular to expose the surface. The importance of mechanical support from the support layer 30 is evident, as the gap 21 has been retained independent of the support requirement. The top surface of the device layer 12 of the SOI wafer 26 is then metallized to provide a reflective surface 13. Optionally, the back surface can be metallized or both surfaces can be metallized as required by device or process design.

Referring to FIG. 2F, thereafter, an array of electrodes 22, 24 on an insulative substrate or ‘package’ 28 is mated with the standoff layer 26 in proper registration and bonded to produce a finished MEMS device 10 in accordance with the invention.

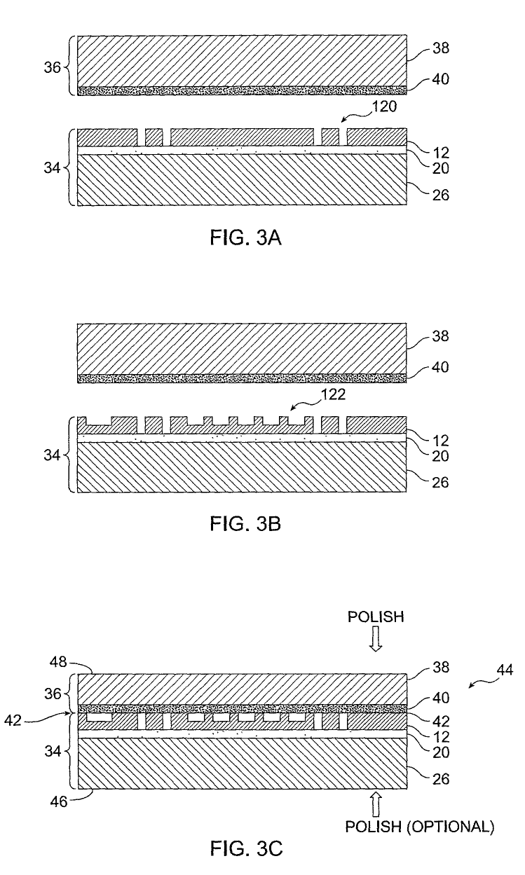

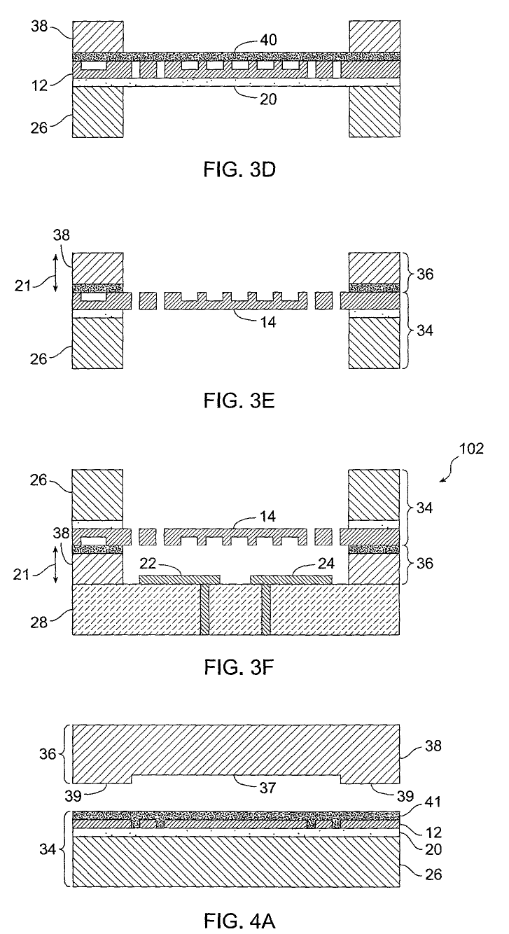

FIG. 3A through FIG. 3F illustrate a process for fabricating MEMS devices 11 having a patterned mirror. Beginning with FIG. 3A, there is shown a side cross-sectional view of two wafers, one 36 to serve as a standoff and the other 34 to serve as support, as shown prior to bonding. Initially SOI wafer 34 provides the accurate standoff. It comprises SOI handle layer 26, BOX 20, and a device layer 12 with a first device pattern 120. Specifically, the device layer 12 is etched according to the first device pattern 120 to define the mirror and gimbal pattern for all devices in an array, of which this is one example device. Then, referring to FIG. 3B, a second device pattern 122 is etched into the surface of the first device pattern to remove mass and thereby increase resonant frequency without unduly sacrificing stiffness. The second device pattern may be, for example, a lattice pattern of concentric rings and ribs.

Referring to FIG. 3C, thereafter silicon wafer 36 comprising silicon substrate 38 with insulator layer 40 is bonded to the SOI wafer 34 with the device layer 12 juxtaposed to the insulator layer 40 at a bonding interface 42 to form a composite wafer 44. Thereafter, the manufacturing process proceeds to a polishing step. Optionally the back side 48 of the silicon substrate 38 is polished to a desired standoff height and ultrafine smoothness. However, the back side 46 of the SOI handle 26 is polished as required by device design. The SOI wafer 34 thereupon becomes the mechanical support for the device layer 12. Thus, the standoff layer can be may arbitrarily thin without having to compromise standoff height for strength.

With the standoff height having been established, then by etching voids in the respective standoff layer and the mechanical support layer the device layer is exposed as covered and protected by the etch stops (FIG. 3D).

Referring to FIG. 3E, the dielectric insulator layers 20, 40 within the cavities formed by the etching are removed to release the device layer 12 and in particular to expose the surface. The importance of mechanical support is evident, as the gap has been retained independent of the support requirement. The bottom surface of the device layer of the SOI wafer 26 is then metallized to provide a reflective surface 13. Optionally, the top surface can be metallized or both surfaces can be metallized as required by device or process design.

Referring to FIG. 3F, thereafter, an array of electrodes 22, 24 in the insulative substrate or ‘package’ 28 is mated with the standoff layer 30 of the silicon wafer 36 in proper registration, and the silicon wafer is bonded to the package 28 to produce a finished MEMS device 10 in accordance with the invention.

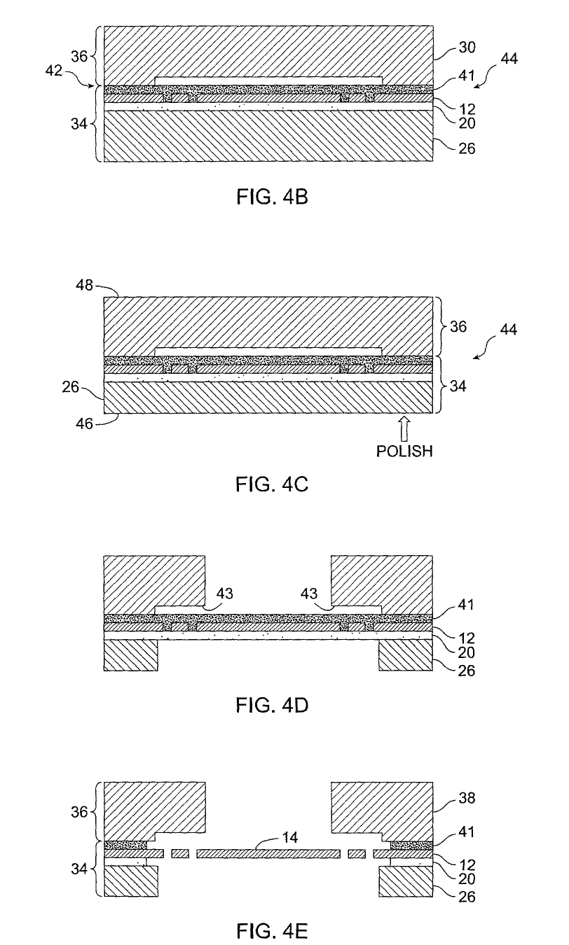

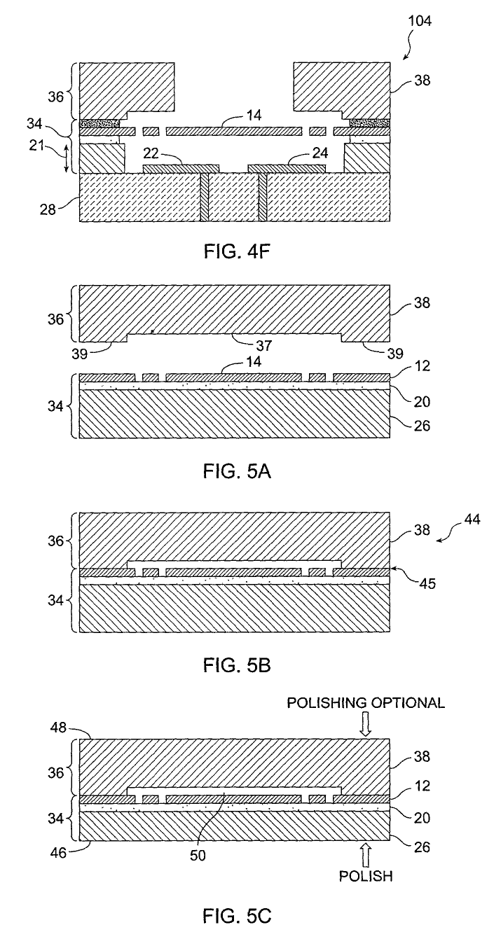

A further process according to the invention is illustrated in FIG. 4A through FIG. 4F. Beginning with FIG. 4A, there is shown a side cross-sectional view of two wafers, one 34 to serve as a standoff and the other 36 to serve as support, as shown prior to bonding. Initially SOI wafer 34 provides inherent support. It comprises SOI handle layer 26, BOX 20, device layer 12 with a device pattern and an optional insulator layer 41 over the device pattern. The silicon wafer 36 has an etch-out region 37 defining an overhanging region 39 when mounted in place. The overhang may be a ring or other pattern as required by device design. The insulator layer 41 is optional or it may be placed on the protective ring 39 or on the etched-out region 37 or on both surfaces as required by the process and design.

Referring to FIG. 4B, thereafter silicon wafer 36 is bonded to the SOI wafer 34 with the insulator layer 41 juxtaposed to the bonding interface 42 to form a composite wafer 44. Thereafter the manufacturing process proceeds to a polishing step wherein the back side 46 of the SOI handle 26 is polished to a desired standoff height and ultrafine smoothness (FIG. 4C). Optionally, the back side 48 of the silicon substrate 36 may also be polished as required by device design.

With the standoff height having been established by the SOI wafer 34, then by etching voids in the respective standoff layer and the mechanical support layer, the device layer is exposed as covered and protected by the etch stops (FIG. 4D). The silicon wafer portion of the support layer has a cavity with a standoff protective lip 43 overlapping the gimbal ring.

Referring to FIG. 4E, the dielectric insulator layers 20, 41 within the cavities formed by the etching are removed to release the device layer 12 and in particular to expose the surface 13. The importance of mechanical support from the SOI wafer as the support layer 30, herein the silicon wafer 36, is evident, as the gap 21 has been retained independent of the support requirement, which herein is provided by the silicon wafer 36.

Referring to FIG. 4F, thereafter, an array of electrodes 22, 24 in the insulative substrate or ‘package’ 28 is mated with the standoff of the SOI wafer portion 34 in proper registration and is bonded to the package 28 to produce a finished MEMS device 10 in accordance with the invention.

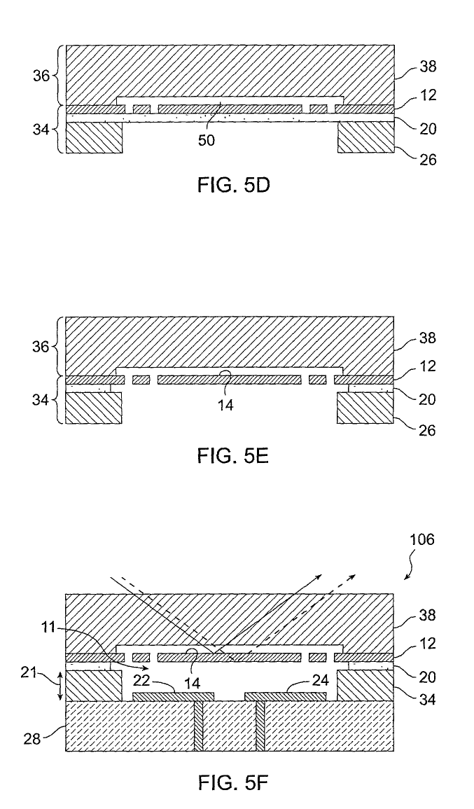

A further process according to the invention is illustrated in FIG. 5A through Figure SF. Beginning with FIG. 5A, there is shown a side cross-sectional view of two wafers, one 34 to serve as a standoff and the other 36 to serve as support, as shown prior to bonding. Initially SOI wafer 34 provides inherent support. It comprises SOI handle layer 26, BOX 20 and a device layer 12 with a device pattern. The silicon wafer 36 has an etch-out region 37 defining an overhanging ring region 39 when mounted in place. Insulation layers are optional. However, the insulation layer should not cover the mirror region. The mirror region could optionally be metallized before further processing (bonding) in order to support front surface reflection.

Referring to FIG. 5B, thereafter silicon wafer 36 is bonded to the SOI wafer 34 with a seal 45 between juxtaposed interface surface to form a composite wafer 44. Silicon fusion bonding may be employed for example, and the seal may be hermetic. Thereafter the manufacturing process proceeds to a polishing step wherein the back side 46 of the SOI handle 26 is polished to a desired standoff height and ultrafine smoothness (FIG. 5C). Optionally, the back side 48 of the silicon substrate 36 may also be polished or thinned as required by device design.

With the standoff height having been established by the SOI wafer 34, then by etching a void in only its standoff layer 26 and not the mechanical support layer 38 of the silicon wafer portion 36, the device layer 12 is contained and not exposed (FIG. 4D). The silicon wafer portion 36 is transparent to light signals passing through it.

Referring to FIG. 5E, the dielectric insulator layer 20 is removed to release the device layer 12. At this point the device layer is temporarily exposed. The device layer can then be metallized at this point in order to support reflection off the back surface.

Referring to FIG. 5F, thereafter, an array of electrodes 22, 24 in the insulative substrate or ‘package’ 28 is mated with the standoff of the SOI wafer portion 34 in proper registration and is sealed to the package 28 to produce a finished MEMS device 10 with a device layer sealed within a sealed cavity 11 in accordance with the invention. The cap is transmissive of selective optical energies, such as certain IR wavelengths, so that the reflective surface can redirect impinging energies. As a further refinement, if it is necessary to suppress internal reflections, anti-refelctive coatings can be provided on one or both surfaces of the silicon substrate 38.

The invention has been explained with reference to specific embodiments. Other embodiments will be evident to those of ordinary skill in the art. For example, silicon nitride could be used as a dielectric and an etch stop for a potassium hydroxide wet etchant as a substitute for the dielectric layers such as the silicon dioxide layers. It is therefore intended that the invention not be limited, except as indicated by the appended claims.

What is claimed is:

1. A method for fabricating ultrathin gaps producing ultrashort standoffs in array structures, the method including the steps of:
preparing a pattern of an exposed device layer on a first dielectric layer in a silicon structure of a SOI wafer to form a patterned device layer; thereafter
mating a silicon substrate layer of a substrate wafer through a second dielectric layer to the patterned device layer of the SOI wafer to form a composite device wherein said patterned device layer is sandwiched between said first and second dielectric layers; thereafter
providing that exposed back surfaces of the composite device are polished to a desired thickness corresponding to a desired standoff height on one side and to at least a minimum height for mechanical strength on an opposing side, as well as to a desired smoothness, said composite device thereupon comprising said silicon substrate layer and said said silicon structure of the SOI wafer; thereafter
etching voids in said silicon substrate layer and said silicon SO wafer to expose said patterned device layer and to form standoffs and mechanical supports, wherein said first and second dielectric layers on both sides of said patterned device layer serve as suitable etch stops and surface protection for said patterned device layer; thereafter;
removing exposed portions of said first and second dielectric layers to release said patterned device layer; and
mating an array package as a package layer with said voids in said silicon substrate layer in proper registration to produce a finished device.

2. The method according to claim 1 further including:
after said removing step, depositing a metal on said patterned device layer to provide a reflective surface.

3. The method according to claim 1 further including:
prior to bonding said SO wafer and said substrate wafer, preparing said substrate wafer to counteract the radius of curvature of said SOI wafer so that said composite structure has a desired flatness.

4. A device fabricated by:
preparing a pattern of an exposed device layer on a first dielectric layer in a silicon structure of a SOI wafer to form a patterned device layer; thereafter
mating a silicon substrate layer of a substrate wafer through a second dielectric layer to the patterned device layer of the SOI wafer to form a composite device wherein said patterned device layer is sandwiched between said first and second dielectric layers; thereafter
providing that exposed back surfaces of the composite device are polished to a desired thickness corresponding to a desired standoff height on one side and to at least a minimum height for mechanical strength on an opposing side, as well as to a desired smoothness, said composite device thereupon comprising said silicon substrate layer and said said silicon structure of the SOI wafer; thereafter
etching voids in said silicon substrate layer and said silicon SOI wafer to expose said patterned device layer and to form standoffs and mechanical supports, wherein said first and second dielectric layers on both sides of said patterned device layer serve as suitable etch stops and surface protection for said patterned device layer; thereafter;
removing exposed portions of said first and second dielectric layers to release said patterned device layer; and
mating an array package as a package layer with said voids in said silicon substrate layer in proper registration to produce a finished device.

5. A method for manufacturing MEMS structures comprising:
providing a patterned device layer on a first substrate layer to yield a patterned device wafer;
bonding a substrate wafer having a second substrate layer to said patterned device wafer to form a composite wafer;
polishing at least one of said two exposed surfaces of said substrate wafer and said patterned device wafer to desired thicknesses;
etching out voids in said substrate wafer and in said patterned device down to both sides of said patterned device layer; and
removing insulation of said patterned device layer to release patterns; and
mounting said composite wafer on a package layer with said second substrate layer juxtaposed to said package layer.

6. The method according to claim 5 further including the step before said bonding step of:
providing an insulative layer upon said patterned device layer as an etch stop to said etching step.

7. The method according to claim 6 wherein said insulative layer providing step comprises silicon fusion bonding of a silicon wafer with a silicon dioxide layer to said patterned device layer.

8. The method according to claim 5 further including:
after said removing step, depositing a metal on said patterned device layer to provide a reflective surface.

9. The method according to claim 6 wherein said insulative layer providing step comprises silicon fusion bonding of a silicon wafer with a silicon nitride layer to said patterned device layer.

10. The method according to claim 5 further including etching out a portion of said patterned device layer to reduce mass of said pattern.

11. The method according to claim 5 further including the step of providing a local seal between said composite layer and said package layer upon bonding with said package layer.

12. The method according to claim 5 further including the step of providing for a protective periphery around patterns in the patterned device layer, said protective periphery formed of voids in the silicon substrate over the patterns.

13. The method according to claim 5 further including the step of providing for a sealed periphery around patterns in the patterned device layer.

14. The method according to claim 5 further including the step of providing for a sealed cap over patterns in the patterned device layer, said cap being transmissive of selective optical energies.

15. A MEMS structure comprising a device manufactured by:
providing a patterned device layer on a first substrate layer to yield a patterned device wafer;
bonding a substrate wafer having a second substrate layer to said patterned device wafer to form a composite wafer;
polishing at least one of said two exposed surfaces of said substrate wafer and said patterned device wafer to desired thicknesses;
etching out voids in said substrate wafer and in said patterned device down to both sides of said patterned device layer; and
removing insulation of said patterned device layer to release patterns; and
mounting said composite wafer on a package layer with said second substrate layer juxtaposed to said package layer.

16. A MEMS structure comprising a device manufactured by:
providing a patterned device layer on a first substrate layer to yield a patterned device wafer;
bonding a substrate wafer having a second substrate layer to said patterned device wafer to form a composite wafer;
polishing said two exposed surfaces of said substrate wafer and said patterned device wafer to desired thicknesses;
etching out voids in said substrate wafer and in said patterned device down to both sides of said patterned device layer; and
removing insulation of said patterned device layer to release patterns; and
mounting said composite wafer on a package layer with said second substrate layer juxtaposed to said package layer.
